(19) United States
(12) Patent Application Publication
(10) Pub. No.: US 2026/0114003 A1
(43) Pub. Date: Apr. 23, 2026

(54) CANDIDATES FOR P-DOPING AND N-DOPING OF TRANSITION METAL DICHALCOGENIDE

(71) Applicant: SAMSUNG ELECTRONICS CO., LTD., Suwon-si (KR)

(72) Inventors: Nikhil Sivadas, Boston, MA (US); Yongwoo Shin, Concord, MA (US); Ali Hamze, Dorchester, MA (US)

(73) Assignee: SAMSUNG ELECTRONICS CO., LTD., Suwon-si (KR)

(21) Appl. No.: 19/076,684

(22) Filed: Mar. 11, 2025

Related U.S. Application Data
(60) Provisional application No. 63/710,362, filed on Oct. 22, 2024.

(51) Int. Cl. H10D 62/80

(52) U.S. Cl. CPC H10D 62/883

(57) ABSTRACT

A doped transition metal dichalcogenide (TMD) by (A) using substitution doping within the fractional limit 0≤x, y≤0.1 and/or (B) adding elements to pristine TMD within the fractional limit 0≤z≤0.1, wherein the TMD is represented by the formula AB₂ where A={Mo, W}, B={S, Se}, and wherein the doped TMD is selected from substitution n-doping: A₍₁₋ₓ₎MₓB_{(2-y)}X_{y}; M={Re, Os}, X={F, Cl, Br, I, OH}; substitution p-doping: A₍₁₋ₓ₎MₓB_{(2-y)}X_{y}; M={V, Nb, Ta, Ti, Zr, Hf}, X={N, P, As, Sb}; additional atom n-doping: AB₂Z_{z}; Z={H, Li, Na, K}; additional atom p-doping: AB₂Z_{z}; Z={N, P, As, F, Cl, Br, I}; or a combination thereof.

### CROSS-REFERENCE TO RELATED APPLICATIONS

This application is based on and claims priority from U.S. Provisional Application No. 63/710,362 filed on Oct. 22, 2024 in the U.S. Patent and Trademark Office, the disclosure of which is incorporated herein by reference in its entirety.

### BACKGROUND

### 1. Field

The subject matter disclosed herein relates to a doped transition metal dichalcogenide (TMD) by (A) using substitution doping within the fractional limit 0≤x, y≤0.1 and/or (B) adding elements to pristine TMD within the fractional limit 0≤z≤0.1, wherein the TMD is represented by the formula AB₂ where A={Mo, W}, B={S, Se}, and wherein the doped TMD is selected from substitution n-doping: A₍₁₋ₓ₎MₓB_{(2-y)}X_{y}; M={Re, Os}, X={F, Cl, Br, I, OH}; substitution p-doping: A₍₁₋ₓ₎MₓB_{(2-y)}X_{y}; M={V, Nb, Ta, Ti, Zr, Hf}, X={N, P, As, Sb}; additional atom n-doping: AB₂Z_{z}; Z={H, Li, Na, K}; additional atom p-doping: AB₂Z_{z}; Z={N, P, As, F, Cl, Br, I}; or a combination thereof.

### 2. Description of the Related Art

The performance of Si-based transistors degrades significantly as the channel thickness is reduced below 4 nm. This limits the application of Si-based transistors for making next-generation transistors that are atomically thin and thereby are faster and more energy efficient.

Compared to Si-based transistors (SOI in FIG. 1), transition metal dichalcogenide (TMD)-based semiconducting van der Waal's materials (MX₂, M=Mo, W; X=S, Se) show robust mobility for channels having an atomically thin layer thickness. Further, as they have a layered structure and the different layers are held together with weak forces, these materials are stable in the monolayer limit with no dangling bonds that can degrade device performance.

However, strategies to controllably p-dope and n-dope TMDs are still absent.

For good device performance, the channel material needs to demonstrate good mobility as well as good carrier concentration. Changing the carrier concentration of TMDs has been proven to be very challenging. To show feasibility of TMDs as an alternative channel material to Si, there is a need to be able to both n-dope and p-dope TMD controllably where the concentration of dopant induced carriers can be tuned.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

Towards the above goal, the present disclosure explores “substitution doping” and adding additional atoms as a strategy to p-dope and n-dope TMDs using MoS₂ as the candidate material of choice.

Substitution doping refers to replacing atoms of the TMD layer with other atoms. Another approach is to add additional atoms that bind to monolayers without replacing any atoms.

In view of the above, the present disclosure provides a list of chemistries that can p-dope TMDs and another list of chemistries for n-doping TMDs and a range for doping concentration.

In particular, the present disclosure provides a list of chemistries to n-dope and p-dope transition metal dichalcogenides (TMDs) (1) using substitution doping within the fractional limit 0≤x, y≤0.1 and/or (2) by adding elements to pristine TMD within the fractional limit 0≤z≤0.1. The list of elements for doping TMDs of the form AB₂ where A={Mo, W}, B={S, Se} are:
1. Substitution n-doping: A₍₁₋ₓ₎MₓB_{(2-y)}X_{y}; M={Re, Os}, X={F, Cl, Br, I, OH};
2. Substitution p-doping: A₍₁₋ₓ₎MₓB_{(2-y)}X_{y}; M={V, Nb, Ta, Ti, Zr, Hf}, X={N, P, As, Sb};
3. Additional atom n-doping: AB₂Z_{z}; Z={H, Li, Na, K};
4. Additional atom p-doping: AB₂Z_{z}; Z={N, P, As, F, Cl, Br, I}; and
5. Combinations of the above lists.

Thus, the present disclosure provides a list of chemistries to n-dope and p-dope transition metal dichalcogenides (TMDs) using substitution doping and/or by adding elements to pristine TMD and proposes the fractional limit 0≤r≤0.1.

The present disclosure allows to both p-dope and n-dope TMDs using the existing monolayer geometries in the most experimentally feasible approach.

The present disclosure is advantageous for various reasons, including because it is easy to implement experimentally.

Thus, the present disclosure includes the following embodiments.

A first embodiment of the present disclosure provides a doped transition metal dichalcogenide (TMD) obtained by (A) using substitution doping within the fractional limit 0≤x, y≤0.1 and/or (B) adding elements to pristine TMD within the fractional limit 0≤z≤0.1,
wherein the TMD is represented by the formula AB₂ where A={Mo, W}, B={S, Se}, and
wherein the doped TMD is:
substitution n-doping: A₍₁₋ₓ₎MₓB_{(2-y)}X_{y}; M={Re, Os}, X={F, Cl, Br, I, OH};
substitution p-doping: A₍₁₋ₓ₎MₓB_{(2-y)}X_{y}; M={V, Nb, Ta, Ti, Zr, Hf}, X={N, P, As, Sb};
additional atom n-doping: AB₂Z_{z}; Z={H, Li, Na, K};
additional atom p-doping: AB₂Z_{z}; Z={N, P, As, F, Cl, Br, I}; or
a combination thereof.

A second embodiment of the present disclosure provides a doped TMD of the first embodiment, wherein the doped TMD is a n-doped TMD and has the following formula:

$${A}_{( 1 - x )} {M}_{x} {B}_{( 2 - y )} {X}_{y} ; M = \{ Re , Os \} , \text{} X = \{ F , Cl , Br , I , OH \} , A = \{ Mo , W \} , B = \{ S , Se \} , 0 \leq x , y \leq 0.1 .$$

A third embodiment of the present disclosure provides a doped TMD of the first embodiment, wherein the doped TMD is a p-doped TMD and has the following formula:

$${A}_{( 1 - x )} {M}_{x} {B}_{( 2 - y )} {X}_{y} ; M = \{ V , Nb , Ta , Ti , Zr , Hf \} , X = \{ N , P , As , Sb \} , A = \{ Mo , W \} , B = \{ S , Se \} , 0 \leq x , y \leq 0.1 .$$

A fourth embodiment of the present disclosure provides a doped TMD of the first embodiment, wherein the doped TMD is a n-doped TMD and has the following formula:

$$A {B}_{2} {Z}_{z} ; Z = \{ H , Li , Na , K \} , A = \{ Mo , W \} , B = \{ S , Se \} , 0 \leq z \leq 0.1 .$$

A fifth embodiment of the present disclosure provides a doped TMD of the first embodiment, wherein the doped TMD is a p-doped TMD and has the following formula:

$$A {B}_{2} {Z}_{z} ; Z = \{ N , P , As , F , Cl , Br , I \} , A = \{ Mo , W \} , B = \{ S , Se \} , 0 \leq z \leq 0.1 .$$

A sixth embodiment of the present disclosure provides a doped TMD of the first embodiment, wherein the doped TMD is the combination thereof.

A seventh embodiment of the present disclosure provides a doped TMD of the second embodiment, wherein X is F.

A eighth embodiment of the present disclosure provides a doped TMD of the second embodiment, wherein X is Cl.

A ninth embodiment of the present disclosure provides a doped TMD of the second embodiment, wherein X is OH.

A tenth embodiment of the present disclosure provides a doped TMD of the third embodiment, wherein X is N.

An eleventh embodiment of the present disclosure provides a doped TMD of the third embodiment, wherein X is P.

A twelfth embodiment of the present disclosure provides a doped TMD of the third embodiment, wherein M={Nb, Ta, Zr, Hf}.

A thirteenth embodiment of the present disclosure provides a doped TMD of the third embodiment, wherein M={Nb, Ta, Zr, Hf} and X={N, P}.

A fourteenth embodiment of the present disclosure provides a doped TMD of the thirteenth embodiment, wherein M is Nb.

A fifteenth embodiment of the present disclosure provides a doped TMD of the thirteenth embodiment, wherein M is Ta.

A sixteenth embodiment of the present disclosure provides a doped TMD of the thirteenth embodiment, wherein M is Zr.

A seventeenth embodiment of the present disclosure provides a doped TMD of the thirteenth embodiment, wherein M is Hf.

A eighteenth embodiment of the present disclosure provides a doped TMD of the fourth embodiment, wherein Z is H.

An nineteenth embodiment of the present disclosure provides a TMD of the fourth embodiment, wherein Z is Li.

A twentieth embodiment of the present disclosure provides a TMD of the fourth embodiment, wherein Z is Na.

### BRIEF DESCRIPTION OF DRAWINGS

The patent or application file contains at least one drawing executed in color. Copies of this patent or patent application publication with color drawing(s) will be provided by the Office upon request and payment of the necessary fee.

Example embodiments of the present disclosure will be more clearly understood from the following detailed description taken in conjunction with the accompanying drawings in which:

FIG. 1 is a graph showing the mobility (μ) of electrons as a function of channel thickness (t_{CH}), and illustrates that for Si on insulators (SOI), the mobility degrades when t_{CH} is below 4 nm, while transition metal dichalcogenides (MoS₂, WSe₂, etc.) show robust mobility for thinner channels.

FIG. 2 shows a computational approach for determining dopants.

FIG. 3 shows graphs to determine candidates for substitution doping in the present disclosure.

FIGS. 4A-4B show larger versions of the graphs in FIG. 3.

FIG. 5 shows graphs to determine candidates for additional atom doping in the present disclosure.

FIGS. 6A-6B show larger versions of the graphs in FIG. 5.

FIG. 7 is a graph showing why a MoS₂ monolayer can be used as a channel material in a proton based ECRAM.

FIG. 8 is a periodic table of the elements showing n-dopant candidates for TMDs.

FIG. 9 is a periodic table of the elements showing p-dopant candidates for TMDs.

FIG. 10 shows a comparison of pristine MoS₂ with Cl doped MoS₂ and Nb doped MoS₂.

FIGS. 11A-11C show larger versions of the graphs of FIG. 10.

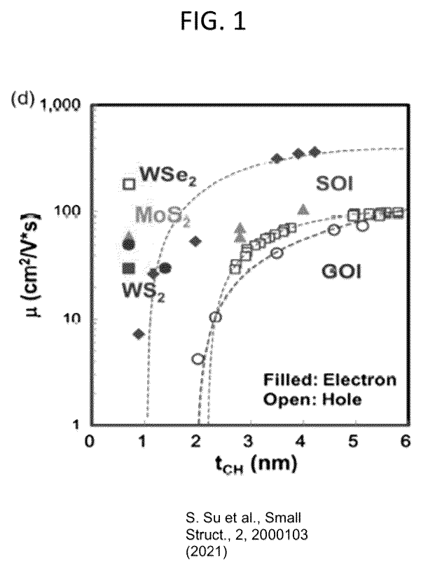

### DETAILED DESCRIPTION OF EXAMPLE EMBODIMENTS

As set forth above, the present disclosure provides a list of chemistries to n-dope and p-dope transition metal dichalcogenides (TMDs) (1) using substitution doping within the fractional limit 0≤x, y≤0.1 and/or (2) by adding elements to pristine TMD within the fractional limit 0≤z≤0.1. The list of elements for doping TMDs of the form AB₂ where A={Mo, W}, B={S, Se} are:
Substitution n-doping: A₍₁₋ₓ₎MₓB_{(2-y)}X_{y}; M={Re, Os}, X={F, Cl, Br, I, OH};
Substitution p-doping: A₍₁₋ₓ₎MₓB_{(2-y)}X_{y}; M={V, Nb, Ta, Ti, Zr, Hf}, X={N, P, As, Sb};
Additional atom n-doping: AB₂Z_{z}; Z={H, Li, Na, K};
Additional atom p-doping: AB₂Z_{z}; Z={N, P, As, F, Cl, Br, I}; and
Combinations of the above lists.

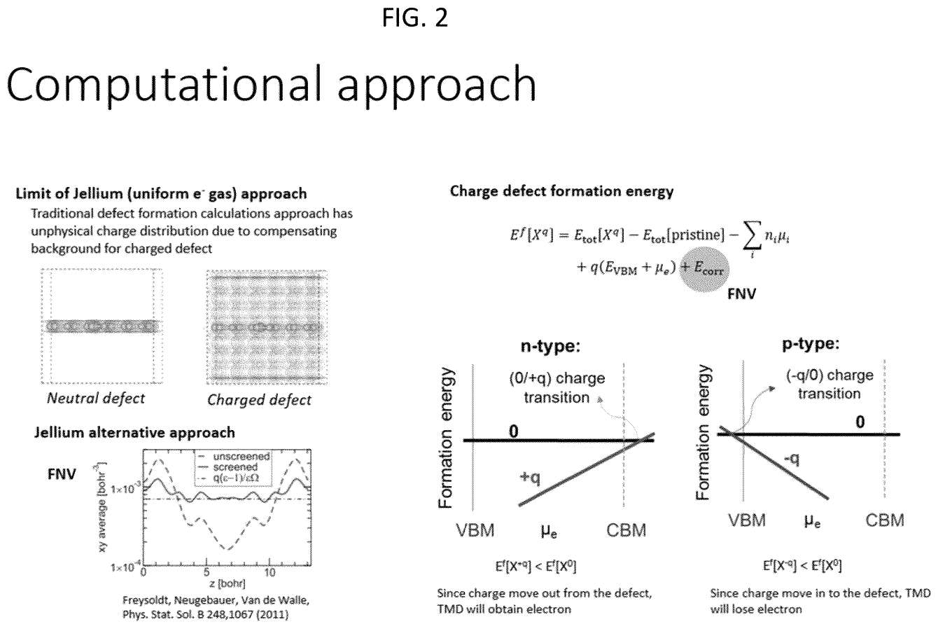

As shown in FIG. 2, the Jellium (uniform e gas) approach is limited. In particular, the traditional defect formation calculations approach has unphysical charge distribution due to compensating background for charged defect.

In the present disclosure, screening is based on defect-band position relative to the pristine band edges, formation energy of substitution, and charge transition levels.

In a large cell (4×4) of monolayer MoS₂ and WSe₂ the present disclosure computes the band structure of pristine TMD as well as TMD with one substitution dopant (either metal replaced by another atom, or S replaced by another atom). The present disclosure also considers the case of adding atoms on TMDs. Additionally, the present disclosure also considers an OH radical occupying the S site as moisture is known to affect the properties of TMDs.

When the bands of the defect states (a) do not induce a mid-gap state (which can act as a scattering center), and (b) the hybridization of the defect bands leads to p-(n-) doping of TMDs where the TMD VBM (CBM) cross the Fermi level (EF), then these are labeled as potential candidates. Additionally, if the dopants do not lead to a significant band rearrangement, the present disclosure labels them as good candidates.

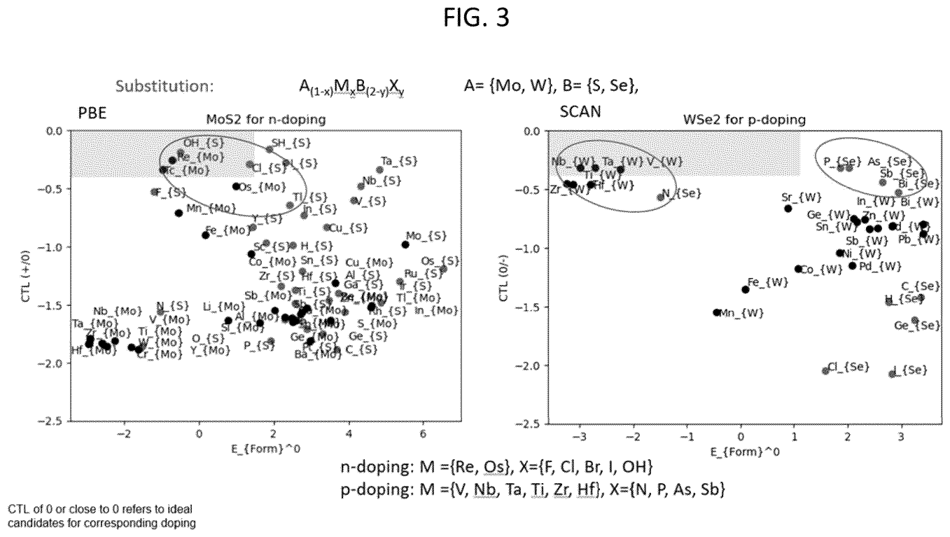

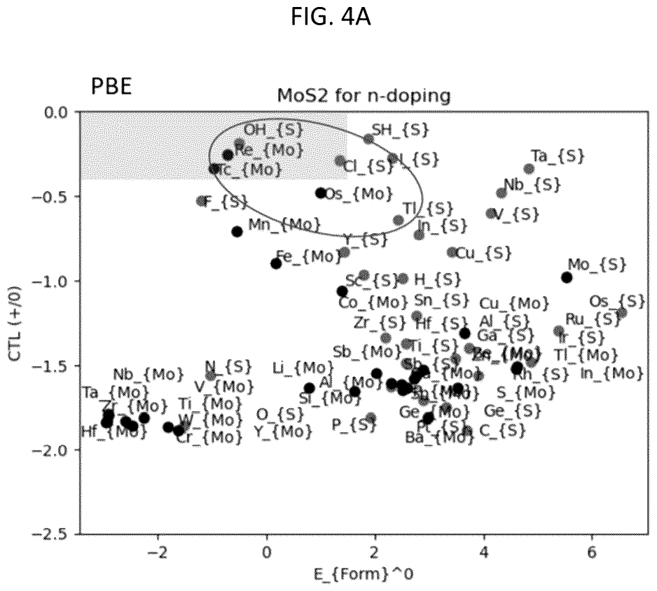

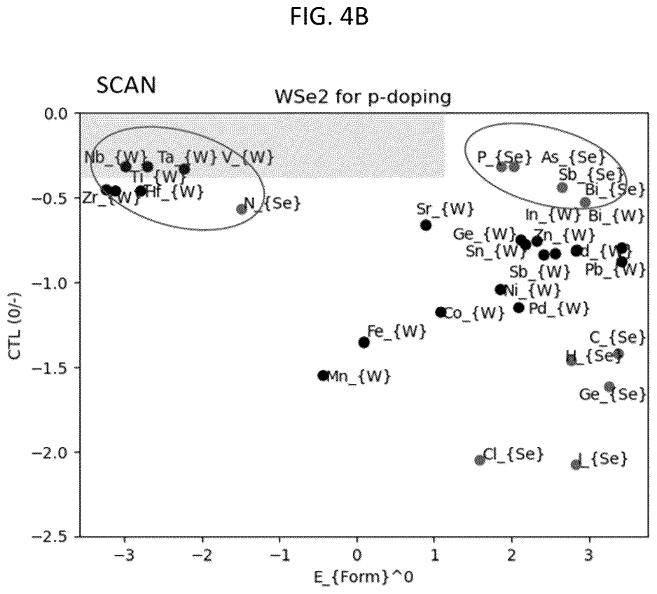

FIG. 3 shows graphs to determine candidates for substitution doping in the present disclosure, and FIGS. 4A and 4B show larger versions of those graphs. A CTL (charge transition level) of 0 or close to 0 in the graphs refers to ideal candidates for corresponding doping. As shown in FIG. 3, for A₍₁₋ₓ₎MₓB_{(2-y)}X_{y} where A={Mo, W} and B={S, Se}, suitable candidates for substitution n-doping include M={Re, Os} and X={F, Cl, Br, I, OH}, and suitable candidates for substitution p-doping include M={V, Nb, Ta, Ti, Zr, Hf} and X={N, P, As, Sb}.

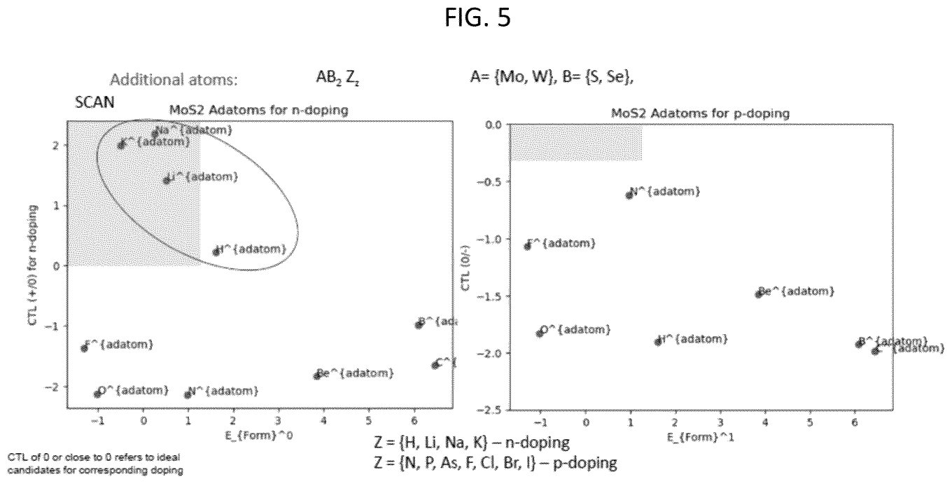

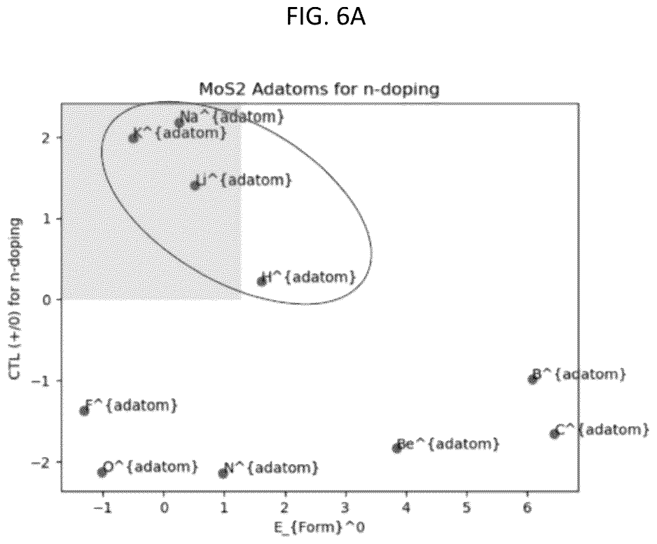

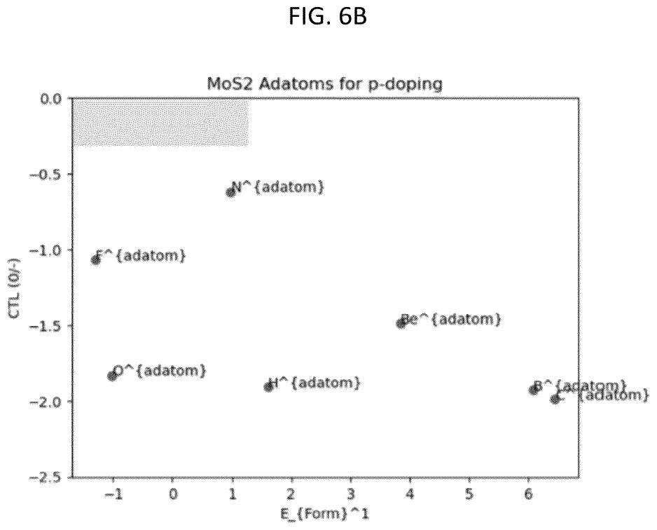

FIG. 5 shows graphs to determine candidates for additional atom doping in the present disclosure, and FIGS. 6A and 6B show larger versions of those graphs. As noted above, a CTL of 0 or close to 0 in the graphs refers to ideal candidates for corresponding doping. As shown in FIG. 5, for AB₂Z_{z} where A={Mo, W} and B={S, Se}, suitable candidates for additional atom n-doping include Z={H, Li, Na, K}, and suitable candidates for additional atom p-doping include Z={N, P, As, F, Cl, Br, I}.

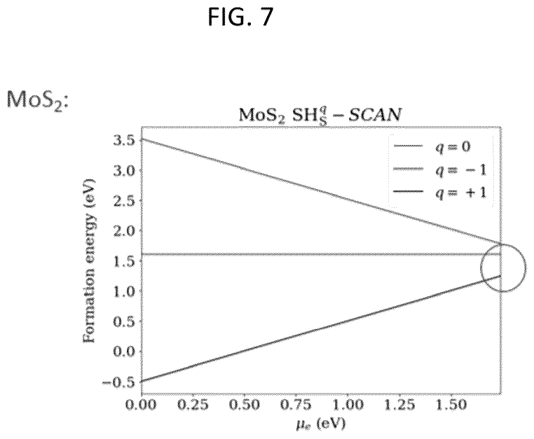

FIG. 7 is a graph showing why a MoS₂ monolayer can be used as a channel material in a proton based ECRAM. That is, calculations according to the present disclosure explain why a MoS₂ monolayer can be used as a channel material in proton based ECRAM: All group 1 elements can be used for this. That is, just like H, using {Li, Na, K} all should work for ECRAM applications.

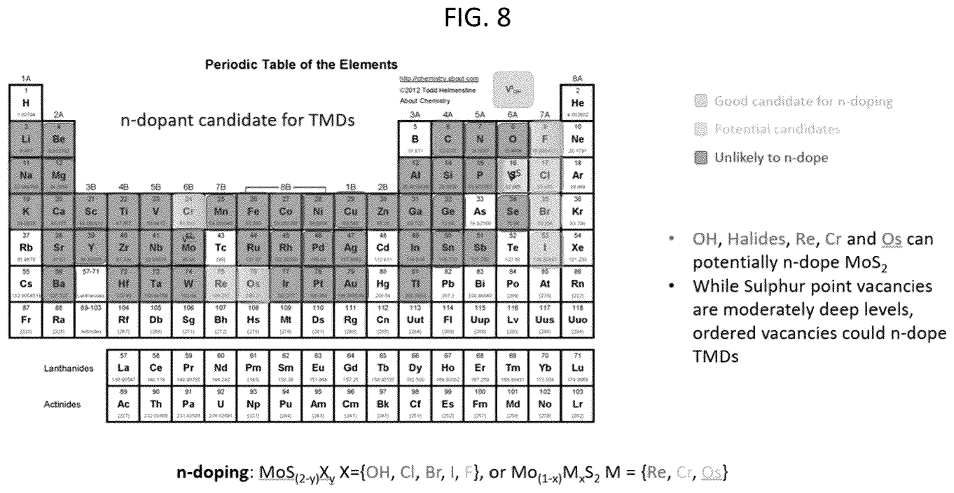

FIG. 8 is a periodic table of the elements showing n-dopant candidates for TMDs. In the periodic table, green indicates a good candidate for n-doping, yellow indicates a potential candidate, and red indicates a candidate that is unlikely to n-dope. As can be seen from the periodic table in this figure, OH, halides, Re, Cr and Os are good candidates to potentially n-dope MoS₂. Further, while sulfur point vacancies are moderately deep levels, ordered vacancies could n-dope TMDs. Thus, in the case of n-doping, for MoS_{(2-y)}X_{y}, X={OH, CI, Br, I, and potentially F}, or for Mo₍₁₋ₓ₎MₓS₂, M={Re and potentially Cr, Os}

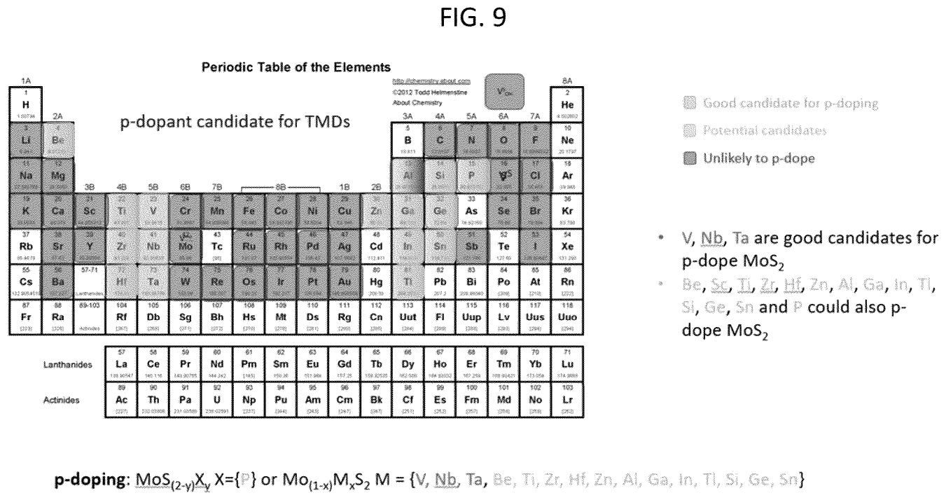

FIG. 9 is a periodic table of the elements showing p-dopant candidates for TMDs. In the periodic table, green indicates a good candidate for p-doping, yellow indicates a potential candidate, and red indicates a candidate that is unlikely to p-dope. As can be seen from the periodic table in this figure, V, Nb, and Ta are good candidates for p-doping MoS₂. Further, Be, Sc, Ti, Zr, Hf, Zn, Al, Ga, In, Tl, Si, Ge, Sn and P could also p-dope MoS₂. Thus, in the case of p-doping, for MoS_{(2-y)}X_{y}, X={potentially P}, or for Mo₍₁₋ₓ₎MₓS₂, M={V, Nb, Ta, and potentially Be, Ti, Zr, Hf, Zn, Al, Ga, In, Tl, Si, Ge, Sn}.

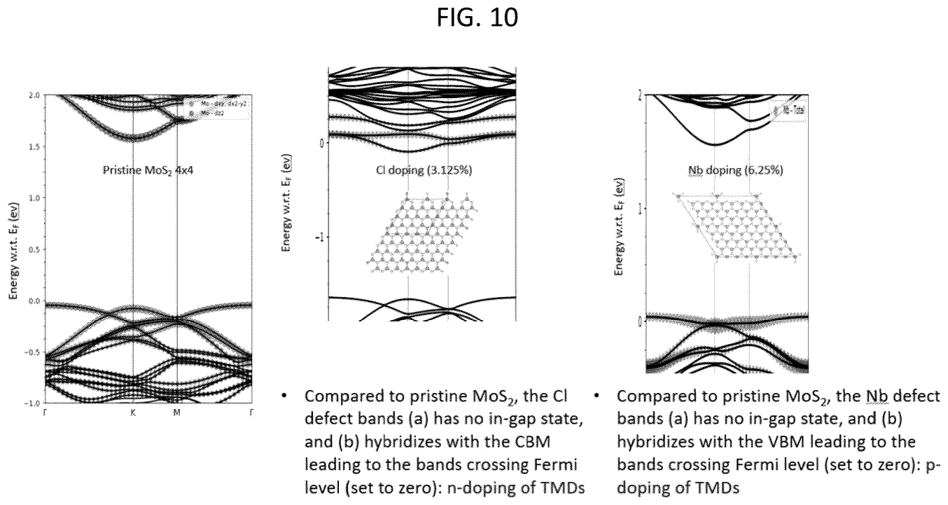

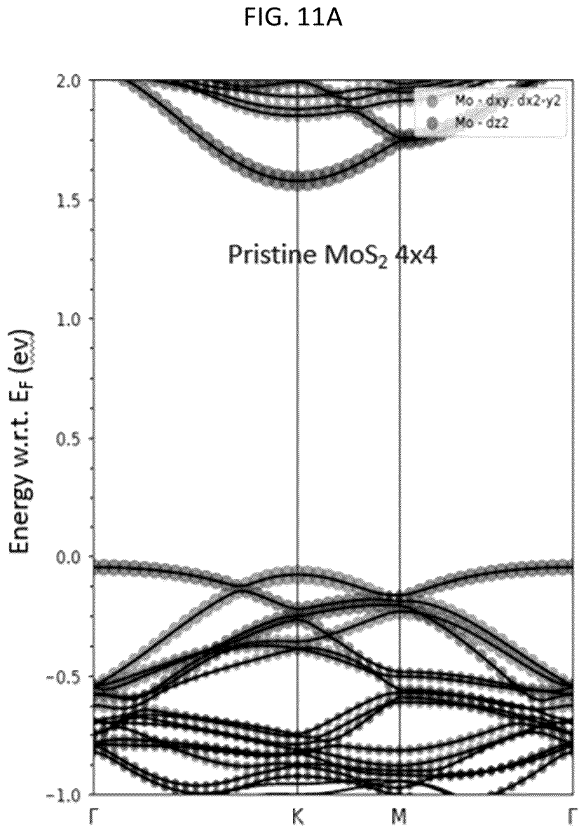

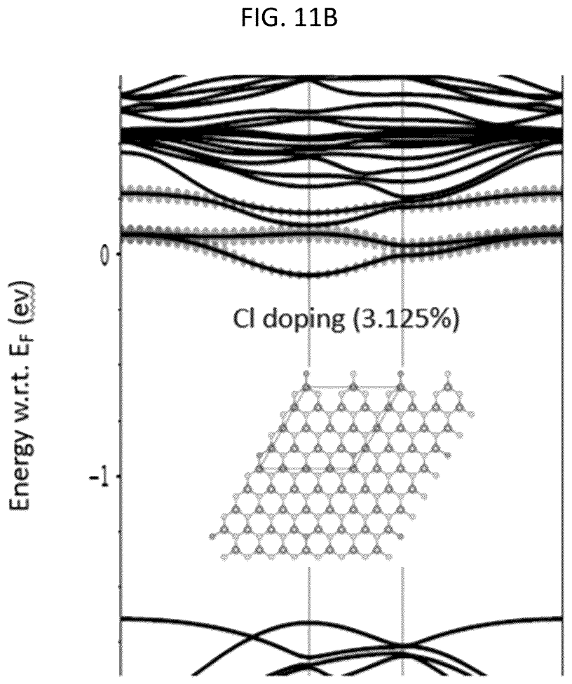

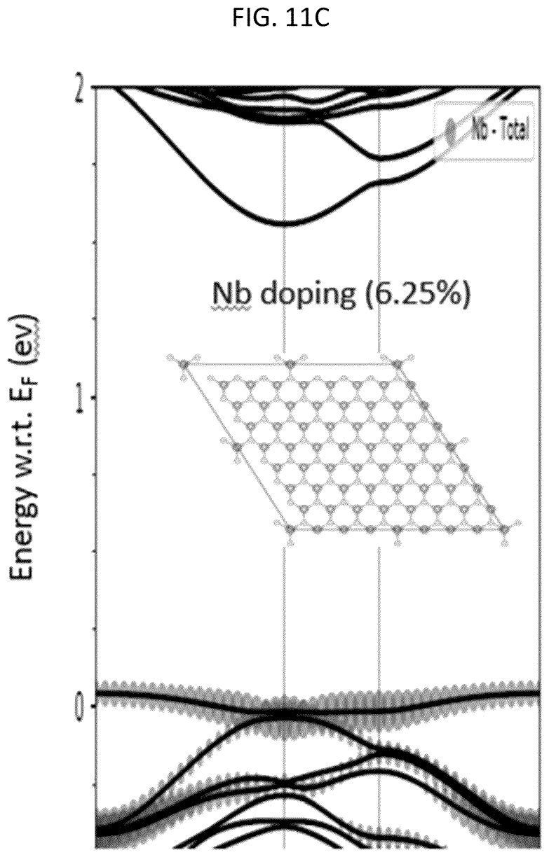

FIG. 10 shows a comparison of pristine MoS₂ with Cl doped MoS₂ and Nb doped MoS₂, and FIGS. 11A-11C show larger versions of the graphs in FIG. 10. In particular, FIG. 10 shows that compared to pristine MoS₂, the Cl defect bands (a) has no in-gap state, and (b) hybridizes with the CBM leading to the bands crossing Fermi level (set to zero), resulting in n-doping of TMDs. Also, FIG. 10 shows that compared to pristine MoS₂, the Nb defect bands (a) has no in-gap state, and (b) hybridizes with the VBM leading to the bands crossing Fermi level (set to zero), resulting in p-doping of TMDs.

The doped TMD in the present disclosure can be made by using typical growth methods like thermal oxidation, atomic layer deposition, pulsed laser deposition, chemical vapor deposition, plasma oxidation, wet anodization or other chemical treatments.

In the present disclosure, as the doping concentration is small (<10%), the negative effect on mobility of electrons is believed to be small.

The present disclosure computed the thermodynamic propensity to dope as well as the electronic structure change for the dopants. Applications include both doping channel materials in field effect transistors as well as modulating the I-V characteristic in electrochemical RAM applications.

That is, the present disclosure can be used to dope TMD channel layers in FET geometry. The same dopants if mobile can be used in ECRAM applications where the channel layer is a TMD.

In particular, the present disclosure can be used to improve existing transistor performance by integrating atomically thin 2D materials as channel layers.

The foregoing is illustrative of exemplary embodiments and is not to be construed as limiting the disclosure. Although a few exemplary embodiments have been described, those skilled in the art will readily appreciate that many modifications are possible in the above embodiments without materially departing from the disclosure.

What is claimed is:

1. A doped transition metal dichalcogenide (TMD) obtained by (A) using substitution doping within the fractional limit 0≤x, y≤0.1 and/or (B) adding elements to pristine TMD within the fractional limit 0≤z≤0.1,
wherein the TMD is represented by the formula AB₂ where A={Mo, W}, B={S, Se}, and
wherein the doped TMD is:
substitution n-doping: A₍₁₋ₓ₎MₓB_{(2-y)}X_{y}; M={Re, Os}, X={F, Cl, Br, I, OH};
substitution p-doping: A₍₁₋ₓ₎MₓB_{(2-y)}X_{y}; M={V, Nb, Ta, Ti, Zr, Hf}, X={N, P, As, Sb};
additional atom n-doping: AB₂Z_{z}; Z={H, Li, Na, K};
additional atom p-doping: AB₂Z_{z}; Z={N, P, As, F, Cl, Br, I}; or
a combination thereof.

2. The doped TMD of claim 1, wherein the doped TMD is a n-doped TMD and has the following formula:
$${A}_{( 1 - x )} {M}_{x} {B}_{( 2 - y )} {X}_{y} ; M = \{ Re , Os \} , X = ( F , Cl , Br , I , OH \} , A = \{ Mo , W \} , B = \{ S , Se \} , 0 \leq x , y \leq 0.1 .$$

3. The doped TMD of claim 1, wherein the doped TMD is a p-doped TMD and has the following formula:
$${A}_{( 1 - x )} {M}_{x} {B}_{( 2 - y )} {X}_{y} ; M = \{ V , Nb , Ta , Ti , Zr , Hf \} , X = \{ N , P , As , Sb \} , A = \{ Mo , W \} , B = \{ S , Se \} , 0 \leq x , y \leq 0.1 .$$

4. The doped TMD of claim 1, wherein the doped TMD is a n-doped TMD and has the following formula:
$$A {B}_{2} {Z}_{z} ; Z = \{ H , Li , Na , K \} , A = \{ Mo , W \} , B = \{ S , Se \} , 0 \leq z \leq 0.1 .$$

5. The doped TMD of claim 1, wherein the doped TMD is a p-doped TMD and has the following formula:
$$A {B}_{2} {Z}_{z} ; Z = \{ N , P , As , F , Cl , Br , I \} , A = \{ Mo , W \} , B = \{ S , Se \} , 0 \leq z \leq 0.1 .$$

6. The doped TMD of claim 1, wherein the doped TMD is said combination thereof.

7. The doped TMD of claim 2, wherein X is F.

8. The doped TMD of claim 2, wherein X is Cl.

9. The doped TMD of claim 2, wherein X is OH.

10. The doped TMD of claim 3, wherein X is N.

11. The doped TMD of claim 3, wherein X is P.

12. The doped TMD of claim 3, wherein M={Nb, Ta, Zr, Hf}.

13. The doped TMD of claim 3, wherein M={Nb, Ta, Zr, Hf} and X={N, P}.

14. The doped TMD of claim 13, wherein M is Nb.

15. The doped TMD of claim 13, wherein M is Ta.

16. The doped TMD of claim 13, wherein M is Zr.

17. The doped TMD of claim 13, wherein M is Hf.

18. The doped TMD of claim 4, wherein Z is H.

19. The doped TMD of claim 4, wherein Z is Li.

20. The doped TMD of claim 4, wherein Z is Na.
